(19) United States
(12) Patent Application Publication
(10) Pub. No.: US 2007/0226586 A1
(43) Pub. Date: Sep. 27, 2007

(54) Apparatus and method for receiving signal in a communication system

(75) Inventors: Sung-Eun Park, Seoul (KR); Thierry Lestable, Staines (GB); Dong-Seek Park, Yongin-si (KR); Jae-Yoel Kim, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/709,934

(22) Filed: Feb. 22, 2007

(30) Foreign Application Priority Data
Feb. 22, 2006 (KR) 17364-2006

(51) Int. Cl. H03M 13/00

(52) U.S. Cl. 714/758

(57) ABSTRACT

An apparatus and method is provided for receiving a signal in a communication system. The signal reception apparatus includes a receiver for receiving a signal, and a decoder for decoding the received signal according to a Low Density' Parity Check (LDPC) decoding scheme. The LDPC decoding scheme includes check node calculation at a particular check node so as to reuse calculation values of some check node calculations among the check node calculations necessary for receiving at the check node messages from all variable nodes connected to the check node and outputting messages to all of the variable nodes connected to the check node.

This application claims the benefit under 35 U.S.C. § 119(a) of a Korean Patent Application filed in the Korean Intellectual Property Office on Feb. 22, 2006 and assigned Serial No. 2006-17364, the disclosure of which is herein incorporated by reference.

### BACKGROUND OF THE INVENTION

1. Field of the Invention

The present invention relates generally to an apparatus and method for receiving signals in a communication system, and in particular, to a signal reception apparatus and method for decoding a Low Density Parity Check (LDPC) code with minimum complexity for check node calculation in a communication system using LDPC codes.

2. Description of the Related Art

The next generation communication system has evolved into a packet service communication system, which is a system for transmitting burst packet data to a plurality of mobile stations (MSs) also designed and is suitable for high-capacity data transmission. It is known that the next generation communication system, together with a turbo code as a channel code, has high performance gain during high-speed data transmission and the system actively considers using the LDPC code that can increase data transmission reliability by efficiently correcting errors caused by noise generated in a transmission channel. The next generation communication systems that are actively considering the use of the LDPC code include an Institute of Electrical and Electronics Engineers (IEEE) 802.16e communication system and an IEEE 802.1 In communication system.

FIG. 1 is a schematic diagram illustrating a structure of a signal transmission apparatus in a general communication system using an LDPC code.

Referring to FIG. 1, the signal transmission apparatus includes an encoder 111, a modulator 113, and a transmitter 115. Here an information vector s that the signal transmission apparatus desires to transmit is generated, and the information vector s is delivered to the encoder 111. The encoder 111 encodes the information vector s into a codeword vector c, i.e. LDPC codeword, using a predetermined coding scheme, and outputs the codeword vector c to the modulator 113. Herein, the coding scheme can be an LDPC coding scheme. The modulator 113 modulates the codeword vector c into a modulation vector m using a predetermined modulation scheme, and outputs the modulation vector m to the transmitter 115. The transmitter 115 performs transmission signal processing on the modulation vector m output from the modulator 113, and transmits the resulting signal to a signal reception apparatus via an antenna ANT.

FIG. 2 is a schematic diagram illustrating a structure of a signal reception apparatus in a general communication system using an LDPC code.

In FIG. 2, the signal reception apparatus includes a receiver 211, a demodulator 213, and a decoder 215. A signal transmitted by a signal transmission apparatus is received at the signal reception apparatus via an antenna ANT, and the received signal is delivered to the receiver 211. The receiver 211 then performs signal reception processing on the received signal, and outputs the reception-processed received vector r to the demodulator 213. Thereafter, the demodulator 213 demodulates the received vector r output from the receiver 211 into a demodulation vector x using a demodulation scheme corresponding to the modulation scheme used in the modulator 113 of the signal transmission apparatus, and outputs the demodulation vector x to the decoder 215. The decoder 215 then decodes the demodulation vector x output from the demodulator 213 using a decoding scheme corresponding to the coding scheme used in the encoder 111 of the signal transmission apparatus, and finally outputs the decoded signal as a restored information vector ŝ. Herein, the decoding scheme is a scheme using an iterative decoding algorithm based on a sum-product algorithm, as described below.

The LDPC code is defined by a parity check matrix in which major elements have a value of 0 and minor elements, other than the elements having a value of 0, have a non-zero value, for example, a value of 1. The LDPC code can be expressed with a bipartite graph, and the bipartite graph is expressed with variable nodes, check nodes, and edges for connecting the variable nodes to the check nodes.

The LDPC code can be decoded using an iterative decoding algorithm based on the sum-product algorithm in the bipartite graph. The sum-product algorithm is a kind of a message passing algorithm, which is an algorithm that exchanges messages through edges in the bipartite graph and updates the messages by calculating output messages from the messages input to the variable nodes or the check nodes. Therefore, a decoder for decoding the LDPC code, because it uses an iterative decoding algorithm based on the sum-product algorithm, has lower complexity than that of a decoder for the turbo code and can be easily implemented with a parallel processing decoder.

A probability mass function for a binary random variable can be expressed in a Log Likelihood Ratio (LLR) as shown in Equation (1).

$$log \frac{{p}_{0}}{{p}_{1}} \qquad ( 1 )$$

where p₀ denotes probability that a bit value will be 0, and p₁ denotes probability that a bit value will be 1.

In addition, a variable node calculation operation and a check node calculation operation for two LLRs, i.e.

$${Λ}_{1} = log \frac{{p}_{0}}{{p}_{1}} and {Λ}_{2} = log \frac{{q}_{0}}{{q}_{1}} ,$$

can be expressed as Equation (2) and Equation (3), respectively.
VAR(Λ₁,Λ₂)=Λ₁+Λ₂ (2)

In Equation (2), VAR(x,y) denotes a function indicating a variable node calculation operation with input degree=2, and the variable node calculation operation indicates an operation of performing a message update by adding up a message x and a message y input to the variable nodes.

$$\begin{matrix}CHK ( {Λ}_{1} , {Λ}_{2} ) = 2 {tanh}^{- 1} ( tanh ( \frac{{Λ}_{1}}{2} ) tanh ( \frac{{Λ}_{2}}{2} ) ) \\ = sgn ( {Λ}_{1} {Λ}_{2} ) min ( \vert {Λ}_{1} \vert , \vert {Λ}_{2} \vert ) + log ( \frac{1 + {ⅇ}^{- \vert {Λ}_{1} + {Λ}_{2} \vert}}{1 + {ⅇ}^{- \vert {Λ}_{1} - {Λ}_{2} \vert}} ) \\ \end{matrix} \qquad ( 3 )$$

where CHK(x,y) denotes a function indicating a check node calculation operation with input degree=2, and where sgn(x) denotes a function indicating a sign of ‘x’.

FIG. 3 is a diagram schematically illustrating the variable node calculation operation shown in Equation (2).

Here, messages Λ₁ and Λ₂ are input to a variable node 300 and undergo the variable node calculation described in Equation (2). The messages are updated according to the variable node calculation result.

FIG. 4 is a diagram schematically illustrating the check node calculation operation shown in Equation (3).

In this instance, messages Λ₁ and Λ₂ are inputs to a check node 400 undergo the check node calculation described in Equation (3), and the messages are updated according to the check node calculation result.

A variable node calculation operation and a check node calculation operation can be defined by converting variable nodes and check nodes with input degree n>3 into combinations of variable nodes or check nodes with input degree n≦3 and sequentially calculating them. For example, for an input degree n, a variable node calculation operation and a check node calculation operation can be expressed as Equation (4) and Equation (5), respectively.
VAR(Λ₁,Λ₂, . . . ,Λₙ)=VAR(Λ₁,VAR(Λ₂, . . . ,Λₙ)) (4)
CHK(Λ₁,Λ₂, . . . ,Λₙ)=CHK(Λ₁,CHK(Λ₂, . . . ,Λₙ)) (5)

Therefore, for an input degree n, the variable node calculation operation and the check node calculation operation can be finally expressed as Equation (6) and Equation (7), respectively, using Equation (4) and Equation (5).

$$\begin{matrix}VAR ( {Λ}_{1} , {Λ}_{2} , … , {Λ}_{n} ) = {Λ}_{1} + {Λ}_{2} + … + {Λ}_{n} & ( 6 ) \\ \begin{matrix}tanh ( \frac{CHK ( {Λ}_{1} , {Λ}_{2} , … , {Λ}_{n}}{2} ) = tanh ( \frac{{Λ}_{1}}{2} ) tanh ( \frac{{Λ}_{2}}{2} ) \\ … tanh ( \frac{{Λ}_{n}}{2} ) \\ \end{matrix} & ( 7 )\end{matrix}$$

FIG. 5 is a schematic diagram illustrating the check node calculation operation shown in Equation (5).

In FIG. 5, because an input degree n of a check node 500 exceeds 3 (n>3), i.e. because n messages Λ₁, Λ₂, . . . , Λₙ are inputs to the check node 500, the messages undergo the check node calculation described in Equation (5). Because the input degree n exceeds 3, the n messages input to the check node 500 can be sequentially calculated by converting them into combinations of check nodes 510, 520, . . . , 530 with input degree n≦3 as described in Equation (5). Here, an exemplary case is shown where (n−1) check nodes with input degree n=2 are concatenated for check node calculation of the check nodes with input degree=n.

FIG. 6 is a schematic diagram illustrating a message update operation from a check node with input degree=dᵥ to a j^{th} variable node.

In FIG. 6, a message outputs to a jₜₕ variable node and is calculated from the remaining (dᵥ−1) messages connected to the check node. In addition, a message update of a check node with input degree=(dᵥ−1) is performed by concatenating (dᵥ−2) check nodes with input degree=2. Therefore, in order to output messages to all of dᵥ variable nodes connected to the check node, a total of dᵥ(dᵥ−2) check node calculation operations with input degree=2 are needed.

As described above, the check node calculation performed for decoding the LDPC code is very high in its calculation complexity. Therefore, there is a need for an LDPC decoding scheme for minimizing complexity of the check node calculation.

### SUMMARY OF THE INVENTION

An aspect of the present invention is to address at least the problems and/or disadvantages and to provide at least the advantages described below. Accordingly, one aspect of the present invention is to provide an apparatus and method for receiving a signal in a communication system using an LDPC code.

Another aspect of the present invention is to provide a signal reception apparatus and method for decoding an LDPC code with minimum complexity for check node calculation in a communication system using an LDPC code.

According to another aspect of the present invention, there is provided an apparatus for receiving a signal in a communication system. The signal reception apparatus includes a receiver for receiving a signal and a decoder for decoding the received signal according to a Low Density Parity Check (LDPC) decoding scheme. The LDPC decoding scheme includes check node calculation at a particular check node so as to reuse calculation values of some check node calculations among the check node calculations necessary for receiving at the check node messages from all variable nodes connected to the check node and outputting messages to all of the variable nodes connected to the check node.

According to another aspect of the present invention, there is provided a method for receiving a signal in a signal reception apparatus of a communication system. The signal reception method includes receiving a signal; and decoding the received signal according to a Low Density Parity Check (LDPC) decoding scheme. The LDPC decoding scheme includes check node calculation at a particular check node so as to reuse calculation values of some check node calculations among the check node calculations necessary for receiving at the check node messages from all variable nodes connected to the check node and outputting messages to all of the variable nodes connected to the check node.

### BRIEF DESCRIPTION OF THE DRAWINGS

The above and other objects, features and advantages of the present invention will become more apparent from the following detailed description when taken in conjunction with the accompanying drawings in which:

FIG. 1 is a schematic diagram illustrating a structure of a signal transmission apparatus in a general communication system using an LDPC code;

FIG. 2 is a schematic diagram illustrating structure of a signal reception apparatus in a general communication system using an LDPC code;

FIG. 3 is a schematic diagram illustrating the variable node calculation operation shown in Equation (2);

FIG. 4 is a schematic diagram illustrating the check node calculation operation shown in Equation (3);

FIG. 5 is a schematic diagram illustrating the check node calculation operation shown in Equation (5);

FIG. 6 is a schematic diagram illustrating a message update operation from a check node with input degree=dᵥ to a j^{th} variable node; and

FIG. 7 is a schematic diagram illustrating an internal structure of a check node processor according to the present invention.

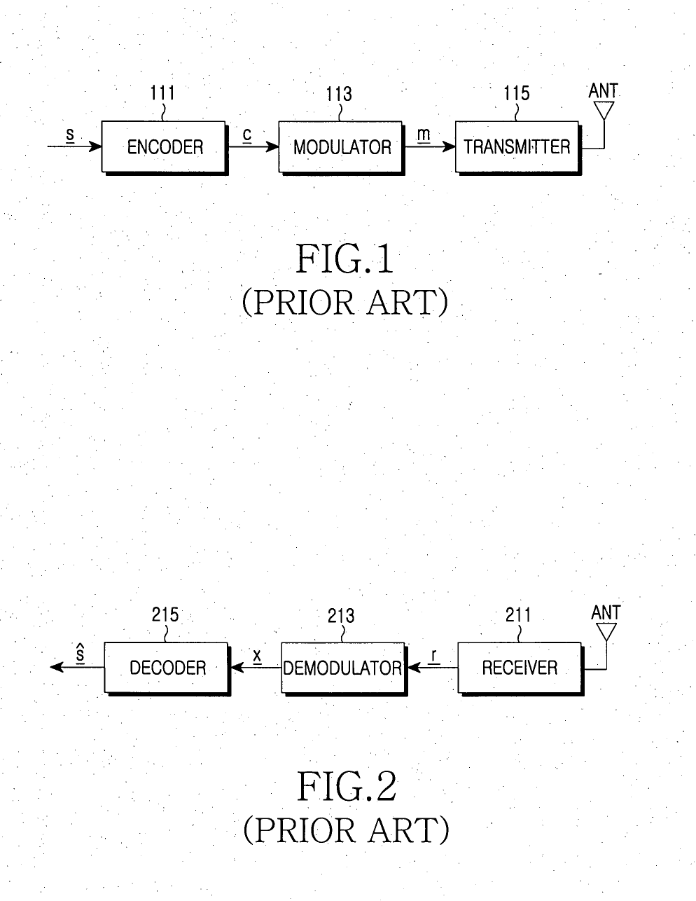

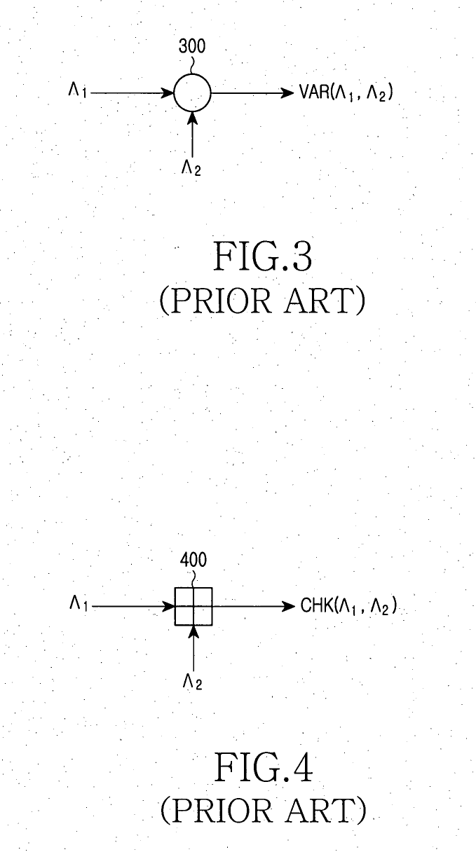

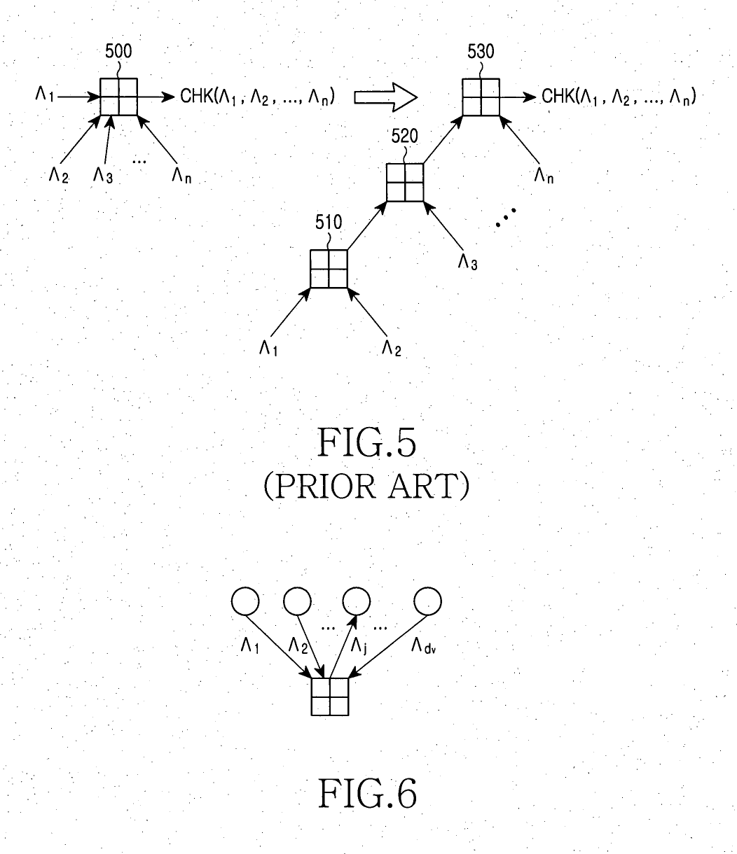

### DETAILED DESCRIPTION OF EXEMPLARY EMBODIMENTS

Preferred embodiments of the present invention will now be described in detail with reference to the annexed drawings. In the following description, a detailed description of known functions and configurations incorporated herein has been omitted for clarity and conciseness.

The present invention provides a signal reception apparatus and method for decoding a Low Density Parity Check (LDPC) code with minimum complexity for check node calculation in a communication system using an LDPC code. Specifically, the present invention provides a signal reception apparatus and method for decoding an LDPC code so as to minimize its calculation complexity by allowing efficient reuse of commonly available calculation values in calculating an output message of each individual check node.

As described above, for two Log Likelihood Ratios (LLRs) Λ₁ and Λ₂, a variable node calculation operation and a check node calculation operation can be expressed as Equation (2) and Equation (3), respectively. In addition, a variable node calculation operation with input degree=n can be expressed as Equation (4) and Equation (6), and a check node calculation operation with input degree=n can be expressed as Equation (5) and Equation (7). For example, for an output message at a first variable node, input messages of a second variable node, a third variable node, . . . , a (dᵥ)^{th} variable node are used at a check node with input degree=dᵥ, and for an output message of a second variable node, input messages of a first variable node, a third variable node, . . . , a (dᵥ)ₜₕ variable node are used. Herein, a calculation value of a function CHK(Λ₃,Λ₄) indicating a check node calculation operation for two LLRs Λ₁ and Λ₂ can be commonly used for the first and second variable node calculation operations, i.e. can be reused. In order to efficiently reuse the calculation value, Equation (8) and Equation (9) are defined as follows.

$$F ( k ) = \{ \begin{matrix}{Λ}_{1} , k = 1 \\ CHK ( F ( k - 1 ) , {Λ}_{k} ) , k = 2 , 3 , … , {d}_{v} - 1\end{matrix} \qquad ( 8 )$$

where F(k) denotes a function indicating an operation of concatenating variable node calculations with input degree=2 in a forward direction.

$$B ( k ) = \{ \begin{matrix}{Λ}_{{d}_{v}} , k = {d}_{v} \\ CHK ( B ( k + 1 ) , {Λ}_{k} ) , k = 2 , 3 , … , {d}_{v} - 1\end{matrix} \qquad ( 9 )$$

where B(k) denotes a function indicating an operation of concatenating variable node calculations with input degree=2 in a reverse direction.

In addition, a message E(j) output from a j^{th} variable node can be expressed as Equation (10).

$$E ( j ) = \{ \begin{matrix}B ( 2 ) , j = 1 \\ CHK ( F ( j - 1 ) , B ( j + 1 ) ) , j = 2 , 3 , … , {d}_{v} - 1 \\ F ( {d}_{v} - 1 ) , j = {d}_{v}\end{matrix} \qquad ( 10 )$$

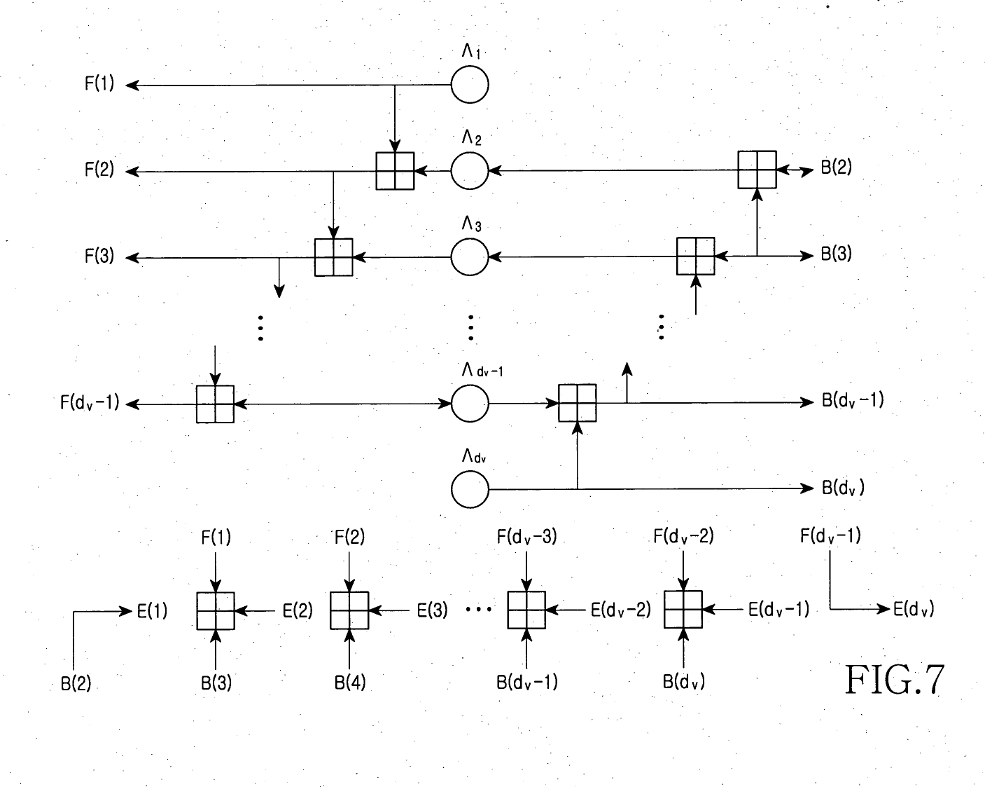

FIG. 7 is a schematic diagram illustrating an internal structure of a check node processor implemented with Equation (8) to Equation (10) according to the present invention.

In this case, the check node processor is implemented taking into account a forward variable node calculation operation described in Equation (8) and a reverse variable node calculation operation described in Equation (9). When a variable node calculation operation is performed as shown in Equation (8) to Equation (10), in order to output messages to all of dᵥ variable nodes connected to a particular check node, a total of (3dᵥ−6) check node calculation operations with input degree=2 are needed. This can reduce the calculation complexity, as compared with the dᵥ(dᵥ−2) check node calculation operations with input degree=2 needed in the general LDPC code decoding process, as described above. By reusing the variable node calculation values reusable as variable node calculation values in performing check node calculation operations, it is possible to implement the check node processor with minimized calculation complexity.

As described above, the present invention provides a scheme for allowing reuse of variable node calculation values reusable in a check node calculation operation in decoding an LDPC code in a communication system, thereby enabling check node operations with minimized calculation complexity. Moreover, by performing the check node operations with minimum calculation complexity, it is possible to increase the decoding efficiency of the LDPC code.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A method for receiving a signal in a signal reception apparatus of a communication system, the method comprising:
receiving a signal; and
decoding the received signal according to a Low Density Parity Check (LDPC) decoding scheme;
wherein the LDPC decoding scheme includes a check node calculation at a particular check node so as to reuse calculation values of some check node calculations among the check node calculations necessary for receiving at the check node messages from all variable nodes connected to the check node and outputting messages to all of the variable nodes connected to the check node.

2. The method of claim 1, wherein the LDPC decoding scheme is expressed as
$$E ( j ) = \{ \begin{matrix}B ( 2 ) , j = 1 \\ CHK ( F ( j - 1 ) , B ( j + 1 ) ) , j = 2 , 3 , … , {d}_{v} - 1 \\ F ( {d}_{v} - 1 ) , j = {d}_{v}\end{matrix}$$
where E(j) denotes a message output from a j^{th} variable node among the plurality of variable nodes, CHK(x,y) denotes a function indicating a check node calculation operation with input degree=2, F(k) denotes a function indicating an operation of concatenating variable node calculations with input degree=2 in a forward direction, and B(k) denotes a function indicating an operation of concatenating variable node calculations with input degree=2 in a reverse direction.

3. The method of claim 2, wherein the F(k) is expressed as
$$F ( k ) = \{ \begin{matrix}{Λ}_{1} , k = 1 \\ CHK ( F ( k - 1 ) , {Λ}_{k} ) , k = 2 , 3 , … , {d}_{v} - 1\end{matrix}$$
where dᵥ denotes an input degree, and Λₖ denotes a Log Likelihood Ratio (LLR).

4. The method of claim 2, wherein the B(k) is expressed as
$$B ( k ) = \{ \begin{matrix}{Λ}_{{d}_{v}} , k = {d}_{v} \\ CHK ( B ( k + 1 ) , {Λ}_{k} ) , k = 2 , 3 , … , {d}_{v} - 1\end{matrix}$$
where dᵥ denotes an input degree, and Λₖ denotes an LLR.

5. An apparatus for receiving a signal in a communication system, the apparatus comprising:
a receiver for receiving a signal; and
a decoder for decoding the received signal according to a Low Density Parity Check (LDPC) decoding scheme;
wherein the LDPC decoding scheme includes a check node calculation at a particular check node so as to reuse calculation values of some check node calculations among the check node calculations necessary for receiving at the check node messages from all variable nodes connected to the check node and outputting messages to all of the variable nodes connected to the check node.

6. The apparatus of claim 5, wherein the LDPC decoding scheme is expressed as
$$E ( j ) = \{ \begin{matrix}B ( 2 ) , j = 1 \\ CHK ( F ( j - 1 ) , B ( j + 1 ) ) , j = 2 , 3 , … , {d}_{v} - 1 \\ F ( {d}_{v} - 1 ) , j = {d}_{v}\end{matrix}$$
where E(j) denotes a message output from a j^{th} variable node among the plurality of variable nodes, CHK(x,y) denotes a function indicating a check node calculation operation with input degree=2, F(k) denotes a function indicating an operation of concatenating variable node calculations with input degree=2 in a forward direction, and B(k) denotes a function indicating an operation of concatenating variable node calculations with input degree=2 in a reverse direction.

7. The apparatus of claim 6, wherein the F(k) is expressed as
$$F ( k ) = \{ \begin{matrix}{Λ}_{1} , k = 1 \\ CHK ( F ( k - 1 ) , {Λ}_{k} ) , k = 2 , 3 , … , {d}_{v} - 1\end{matrix}$$
where dᵥ denotes an input degree, and Λₖ denotes a Log Likelihood Ratio (LLR).

8. The apparatus of claim 6, wherein the B(k) is expressed as
$$B ( k ) = \{ \begin{matrix}{Λ}_{{d}_{v}} , k = {d}_{v} \\ CHK ( B ( k + 1 ) , {Λ}_{k} ) , k = 2 , 3 , … , {d}_{v} - 1\end{matrix}$$
where dᵥ denotes an input degree, and Λₖ denotes an LLR.
